(19) United States
(12) Patent Application Publication
(10) Pub. No.: US 2026/0040467 A1
(43) Pub. Date: Feb. 5, 2026

(54) CONNECTOR ASSEMBLY AND VEHICLE ELECTRONIC CONTROL UNIT INCLUDING SAME

(71) Applicant: HL MANDO CORPORATION, Gyeonggi-do (KR)

(72) Inventor: Minseong KIM, Gyeonggi-do (KR)

(21) Appl. No.: 18/948,475

(22) Filed: Nov. 15, 2024

(30) Foreign Application Priority Data
Aug. 2, 2024 (KR) 10-2024-0103075

(51) Int. Cl. H05K 5/02; H05K 5/00; H05K 5/06

(52) U.S. Cl. CPC H05K 5/0247; H05K 5/003; H05K 5/0056; H05K 5/064

(57) ABSTRACT

Disclosed are a connector assembly and a vehicle electronic control unit including the same. The connector assembly and the vehicle electronic control unit including the same according to the present disclosure may include a housing, a printed circuit board (PCB) provided inside the housing, a terminal electrically connected to the PCB and formed of a first material such that at least a portion of the terminal is exposed to an outside of the housing, and a sacrificial member of which at least a portion is adjacent to the terminal and exposed to the outside of the housing, wherein the sacrificial member may be formed of a second material having higher reactivity than the first material.

### CROSS-REFERENCE TO RELATED APPLICATION

This application claims the benefit of Korean Patent Application No. 10-2024-0103075, filed on Aug. 2, 2024 in the Korean Intellectual Property Office, the disclosure of which is incorporated herein by reference.

### BACKGROUND

### 1. Field

Embodiments of the present disclosure relate to a connector assembly and a vehicle electronic control unit including the same, and more specifically, to a connector assembly, in which a terminal is prevented from being corroded by moisture entering a housing of a product, and a vehicle electronic control unit including the same.

### 2. Description of the Related Art

Electronic control units (ECUs) which electronically control various mechanical apparatuses such as brake systems and suspension systems are mounted in vehicles, and the ECUs process information provided from sensors or switches installed on parts of the vehicles to improve the ride comfort and stability of the vehicles or perform electronic control for providing various conveniences to drivers and occupants.

In general, such a vehicle ECU may be formed as a structure including a case including an upper cover and a lower base, a printed circuit board (PCB) accommodated in the case, a connector coupled to a front end of the PCB for connection with an external socket, and the like.

Since the vehicle ECU is frequently mounted outside the vehicle such as in an engine compartment rather than inside the vehicle and includes a highly integrated control circuit, the vehicle ECU requires a sealing structure capable of preventing moisture or foreign matter from entering the case. The sealing structure of the ECU may be provided to protect the internal PCB and the like through a method of assembling the connector with the cover and the base in a state in which a sealing member is inserted into a fastening portion between the cover and the base, and the connector.

FIG. 1 is a cross-sectional view illustrating main portions of the conventional vehicle ECU. Referring to FIG. 1, the conventional vehicle ECU includes a housing 10, a PCB 20 provided inside the housing 10, and a terminal 30 of which one end is electrically connected to the PCB 20 and the other end protrudes outward from the housing 10. In this case, the housing 10 includes a potting part 11 provided therein to prevent moisture from entering the housing 10 through the terminal 30 from the outside.

However, as illustrated in FIG. 1, in the conventional vehicle ECU, since the terminal 30 of which at least a portion is exposed to the outside to be electrically connected to another device of the housing 10 is easily exposed to moisture W, there is a problem of the terminal 30 being corroded. In the conventional vehicle ECU, not only the lifetime of a product can be reduced due to the corrosion of the terminal 30, but a fire or the like can also occur due to a leakage current.

In addition, in the conventional vehicle ECU, as the corrosion of the terminal 30 exposed to the outside of the housing 10 spreads to the terminal 30 disposed in the housing 10, the potting part 11 is damaged, and thus there is a problem that the moisture W enters the housing 10, thereby causing damage to the PCB 20.

In addition, although not illustrated in the drawing, the conventional vehicle ECU has a sensor that detects the moisture entering the housing 10 in order to prevent damage to the product due to the moisture entering the housing 10 and is provided on the PCB 20, which increases manufacturing costs.

### SUMMARY

Therefore, it is one aspect of the present disclosure to provide a connector assembly capable of preventing moisture from entering the inside of a housing through a terminal exposed to the outside of the housing, and a vehicle electronic control unit including the same.

It is another aspect of the present disclosure to provide a connector assembly capable of significantly delaying corrosion of a terminal exposed to the outside of a housing, and a vehicle electronic control unit including the same.

It is still another aspect of the present disclosure to provide a connector assembly capable of preventing damage to a potting part inside a housing occurring due to corrosion of a terminal located outside the housing spreading to the terminal located inside the housing, and a vehicle electronic control unit including the same.

It is yet another aspect of the present disclosure to provide a connector assembly capable of detecting moisture entering a housing without using a separate moisture detection sensor, and a vehicle electronic control unit including the same.

In accordance with one aspect of the present disclosure, there is provided a connector assembly including a housing, a printed circuit board (PCB) provided inside the housing, a terminal electrically connected to the PCB and formed of a first material such that at least a portion of the terminal is exposed to an outside of the housing, and a sacrificial member of which at least a portion is adjacent to the terminal and exposed to the outside of the housing, wherein the sacrificial member is formed of a second material having higher reactivity than the first material.

The sacrificial member may be formed to be spaced apart from the terminal so as not to be electrically connected to the terminal and may be electrically connected to the terminal through moisture entering the housing.

The housing may include a first accommodation part formed by a rib provided to surround an outer peripheral side of the terminal on an outer side of one surface of the housing in which the terminal is disposed.

The at least a portion of the sacrificial member may be provided to be disposed in the first accommodation part.

The housing may include a potting part provided on an inner side of one surface of the housing in which the terminal is disposed.

The housing may further include a second accommodation part formed by a rib provided to surround an outer peripheral side of the potting part provided on the inner side of one surface of the housing in which the terminal is disposed.

At least a portion of the sacrificial member may be provided to be disposed in the second accommodation part.

The sacrificial member may be riveted to the housing, insert-injection-molded with the housing, coupled to the housing by a fastening member, or press-fitted to the housing.

The sacrificial member may include an extension extending from one end side of the sacrificial member disposed outside the housing to an inside of the housing and an auxiliary sacrificial member fixedly provided inside the housing and directly connected to the extension.

The auxiliary sacrificial member may be formed of any one of the second material, a third material having higher reactivity than the second material, and a fourth material having higher reactivity than the first material and lower reactivity than the second material.

The auxiliary sacrificial member may be formed to have a greater volume than the sacrificial member.

The extension may be disposed in the potting part.

The housing may include a third accommodation part formed by a rib provided to surround an outer peripheral side of the auxiliary sacrificial member on an inner side of one surface of the housing in which the auxiliary sacrificial member is disposed.

The housing may include an auxiliary potting part provided in the third accommodation part to surround at least a portion of the auxiliary sacrificial member.

The sacrificial member may be integrally formed with the auxiliary sacrificial member and provided to be insert-injection-molded with the housing.

The sacrificial member may include an extension extending from one end side of the sacrificial member disposed outside the housing to an inside of the housing and a PCB connector electrically connected to the PCB at an end portion side of the extension.

The sacrificial member together with the extension and the PCB connector may be formed of a conductive metal

The PCB may be provided to output a diagnostic trouble code (DTC) or block power when disconnected from the PCB connector.

The first material may include Cu, and the second material may include Zn.

In accordance with another aspect of the present disclosure, there is provided a vehicle electronic control unit which includes a connector assembly, wherein the connector assembly includes a housing, a PCB provided inside the housing, a terminal electrically connected to the PCB and formed of a first material such that at least a portion of the terminal is exposed to an outside of the housing, and a sacrificial member of which at least a portion is adjacent to the terminal and exposed to the outside of the housing, wherein the sacrificial member is formed of a second material having higher reactivity than the first material.

### BRIEF DESCRIPTION OF THE DRAWINGS

These and/or other aspects of the disclosure will become apparent and more readily appreciated from the following description of the embodiments, taken in conjunction with the accompanying drawings of which:

FIG. 1 is a cross-sectional view illustrating main portions of the conventional vehicle electronic control unit;

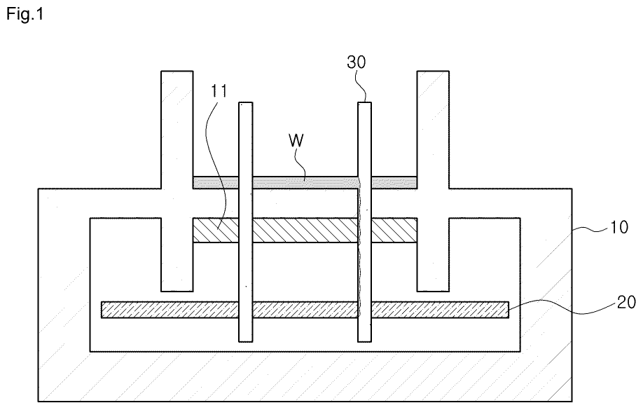

FIG. 2 is a cross-sectional view illustrating main portions of a vehicle electronic control unit including a connector assembly according to one embodiment of the present disclosure;

FIG. 3 is a conceptual view for describing a cathodic protection system between a terminal and a sacrificial member in the vehicle electronic control unit including the connector assembly according to one embodiment of the present disclosure;

FIG. 4 is a cross-sectional view illustrating main portions of a vehicle electronic control unit including a connector assembly according to one embodiment of the present disclosure;

FIG. 5 is a cross-sectional view illustrating main portions of a vehicle electronic control unit including a connector assembly according to one embodiment of the present disclosure; and

FIG. 6 is a cross-sectional view illustrating main portions of a vehicle electronic control unit including a connector assembly according to one embodiment of the present disclosure;

### DETAILED DESCRIPTION

Hereinafter, embodiments of the present disclosure will be described in detail with reference to the accompanying drawings. The following embodiments are provided to sufficiently convey the spirit of the present disclosure to those skilled in the art. The present disclosure is not limited to the embodiments disclosed herein and may be implemented in different forms. In the drawings, portions which are not related to the description may be omitted to clarify the present disclosure, and sizes of components may be exaggerated to facilitate understanding of the present disclosure.

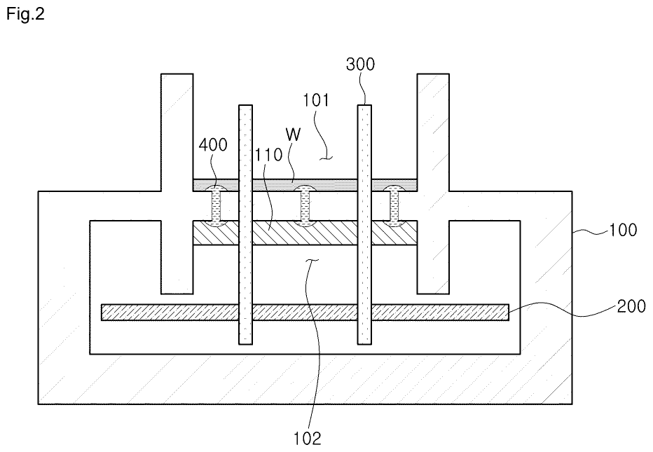

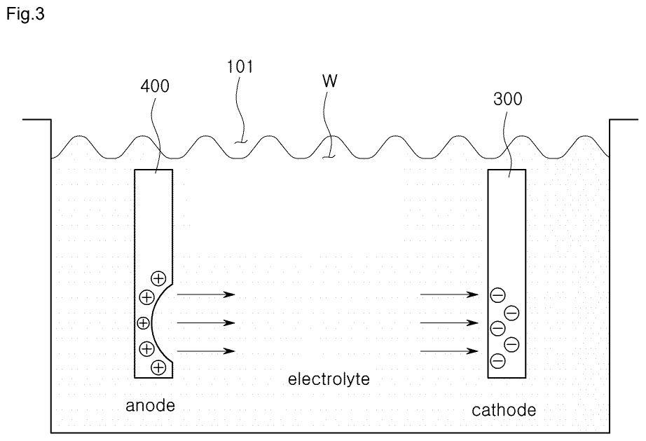

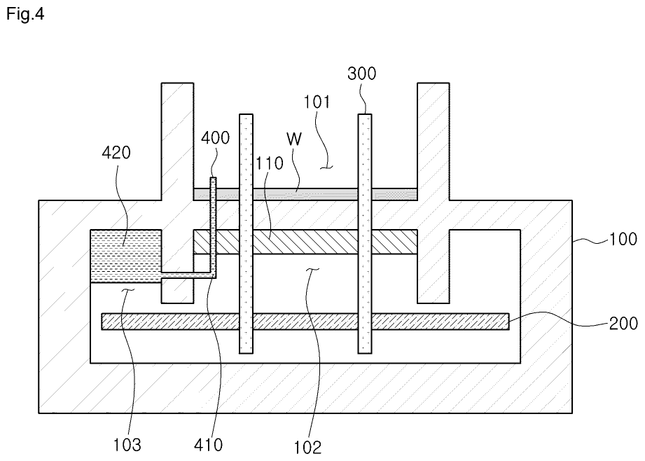

FIG. 2 is a cross-sectional view illustrating main portions of a vehicle electronic control unit including a connector assembly according to one embodiment of the present disclosure. In addition, FIG. 3 is a conceptual view for describing a cathodic protection system between a terminal and a sacrificial member in the vehicle electronic control unit including the connector assembly according to one embodiment of the present disclosure. In addition, each of FIGS. 4 to 6 is a cross-sectional view illustrating main portions of a vehicle electronic control unit including a connector assembly according to one embodiment of the present disclosure.

Referring to FIGS. 2 to 6, a connector assembly and a vehicle electronic control unit including the same according to one embodiment of the present disclosure may include a housing 100, a printed circuit board (PCB) 200 provided inside the housing 100, a terminal 300 of which one end side is electrically connected to the PCB 200 and the other end side is exposed to the outside of the housing 100, and a sacrificial member 400 which is adjacent to the terminal 300 and is exposed to the outside of the housing 100.

More specifically, the housing 100 may be a case forming the overall exterior of the connector assembly and the vehicle electronic control unit including the same according to one embodiment of the present disclosure, and although not illustrated in the drawings, may include at least two parts which may be assembled to form an inner space and disassembled. In addition, the housing 100 may include a sealing member to prevent moisture from entering the inner space from the outside when the parts are assembled, or may be waterproofed through various well-known methods.

In addition, the housing 100 may include a potting part 110 provided inside a portion through which the terminal 300 having one end side disposed inside the housing 100 and the other end side disposed outside the housing 100 passes. In this case, the potting part 110 may be formed of an epoxy resin, silicone, or urethane resin in order to protect the terminal 300 from impacts and vibrations and prevent the terminal 300 from being corroded by moisture.

In addition, the housing 100 may include a first accommodation part 101 formed to accommodate a portion of a connector 500 fastened to the connector assembly according to one embodiment of the present disclosure by a rib provided to surround an outer peripheral side of the terminal 300 disposed outside the housing 100.

In addition, the housing 100 may include a second accommodation part 102 formed such that the potting part 110 is firmly seated and accommodated by a rib provided to surround an outer peripheral side of the terminal 300 disposed inside the housing 100. That is, the second accommodation part 102 may be provided opposite to the first accommodation part 101 based on one sidewall of the housing 100 through which the terminal 300 is disposed to pass. In addition, as illustrated in FIG. 2, the ribs forming the first accommodation part 101 and the second accommodation part 102 may be continuously formed from the outside to the inside of the housing 100, or although not illustrated in the drawings, the ribs may be separately formed on the outside and the inside of the housing 100.

In addition, since the housing 100 may include a plurality of terminals 300, the first accommodation part 101 provided to surround the outer peripheral side of the terminal 300 and the second accommodation part 102 for firm seating and accommodation of the potting part 110 may be provided as a plurality of first accommodation parts 101 and a plurality of second accommodation parts 102 on various surfaces of the housing 100.

The PCB 200 includes various electronic elements and electrical wiring for controlling components electrically operated by the vehicle electronic control unit including the connector assembly according to one embodiment of the present disclosure and is disposed inside the housing 100. In addition, as illustrated in FIG. 2, the PCB 200 may be provided in the form of a single board, or although not illustrated in the drawings, may be provided as a plurality of divided or stacked boards. In addition, the PCB 200 may be fixedly supported by a boss, hook, or the like provided inside the housing 100.

In addition, the PCB 200 may be prevented from being damaged by moisture and foreign matter entering the housing 100 by applying waterproofing agent or the like on a surface in a state in which the electronic elements and electrical wiring are mounted on the PCB 200.

As illustrated in FIG. 2, the terminal 300 may be provided to pass through one surface of the housing 100 such that one end side of the terminal 300 may be disposed inside the housing 100 and electrically connected to the PCB 200 and the other end side thereof is disposed outside the housing 100. The terminal 300 may be for connecting with an actuator and the like electrically connected to the connector assembly and the vehicle electronic control unit including the same according to one embodiment of the present disclosure and may be formed of a first material, which is a conductive metal including Cu or the like.

In addition, as illustrated in FIG. 2, two terminals 300 may be disposed in parallel, or the plurality of terminals 300 may be disposed to form various shapes when viewed from above or provided to be accommodated in the first accommodation part 101 provided outside the housing 100. In this case, an end portion of the terminal 300 disposed outside the housing 100 may be formed with a lower height than an upper end of the rib of the housing 100 forming the first accommodation part 101, thereby preventing deformation of or damage to the terminal 300. In addition, the terminal 300 may be prevented from being separated from the housing 100 or the PCB 200 due to impacts and vibrations by the potting part 110.

The sacrificial member 400 may include a second material having higher reactivity than the first material constituting the terminal 300, and at least a portion of the sacrificial member 400 may be provided to be adjacent to the terminal 300 and exposed to the outside of the housing 100. In this case, the second material may include Zn or an aluminum alloy having higher reactivity than the first material including Cu or the like. That is, the first material and the second material may each be provided as a metal, and the second material may be provided as a metal having a greater ionization tendency and being more easily oxidized than the first material.

More specifically, the sacrificial member 400 may be formed to be sufficiently spaced apart from the terminal 300 so as not to be directly electrically connected to the terminal 300 and disposed adjacent to the terminal 300 so as to be electrically connected to the terminal 300 through moisture entering the housing 100. To this end, as illustrated in FIG. 2, a portion of the sacrificial member 400 exposed to the outside of the housing 100 may be disposed in the first accommodation part 101 with the terminal 300. Accordingly, the sacrificial member 400 may be corroded earlier than the terminal 300 by moisture W entering the first accommodation part 101, thereby delaying corrosion of the terminal 300.

In addition, the sacrificial member 400 may be formed to be lower than an upper end of the rib of the housing 100 forming the first accommodation part 101 and formed with a lower height than an end portion of the terminal 300 disposed in the first accommodation part 101 to prevent the connector assembly according to one embodiment of the present disclosure from being deformed to damaged when connected to another connector.

Particularly, when connectors are generally electrically coupled, since a socket coupled to the terminal 300 exposed to the outside of the housing 100 is coupled to a portion of an end portion of the terminal 300 without being coupled to the entire portion of the terminal 300 exposed to the outside of the housing 100, a height of the sacrificial member 400 disposed in the first accommodation part 101 is lower than a depth of the socket, thereby preventing the sacrificial member 400 from being deformed or damaged when connectors are fastened.

Meanwhile, as described above with reference to FIG. 3, a cathodic protection system in which corrosion due to moisture W entering the first accommodation part 101 first occurs on the sacrificial member 400 rather than on the terminal 300 will be described below.

First, corrosion means a change that occurs on the surface of a metal due to a chemical or electrical reaction with surrounding materials, and metal corrosion generally means that a surface of a metal reacts with oxygen and is oxidized. Particularly, a metal may be more easily corroded when coming into contact with a liquid phase. The cathodic protection system is intended to prevent such corrosion and delay corrosion of the terminal 300 using the sacrificial member 400.

More specifically, the terminal 300 formed of the first material and the sacrificial member 400 formed of the second material having higher reactivity than the first material may be electrically connected through moisture W entering the first accommodation part 101. In this case, a potential difference occurs between the terminal 300 and the sacrificial member 400, the terminal 300 formed of the first material as described above may act as a cathode, and the sacrificial member 400 formed of the second material having higher reactivity than the first material may act as an anode, and the moisture W may act as an electrolyte.

Accordingly, electrons in the sacrificial member 400 may move toward the terminal 300 so that the sacrificial member 400 may be oxidized and the terminal 300 may be reduced. That is, the sacrificial member 400 may be corroded first instead of the terminal 300, thereby delaying the corrosion of the terminal 300.

In addition, although not illustrated in the drawings, when the moisture W does not enter the first accommodation part 101, since a state in which the terminal 300 and the sacrificial member 400 are not electrically connected is maintained, the electrons do not move between the terminal 300 and the sacrificial member 400.

Hereinafter, various examples of a layout and a structure of the sacrificial member 400 in the connector assembly and the vehicle electronic control unit including the same according to one embodiment of the present disclosure will be described.

First, as illustrated in FIG. 2, a sacrificial member 400 may be riveted at a lower surface side of a first accommodation part 101 such that one end of the sacrificial member 400 is disposed in the first accommodation part 101 and the other end thereof may be disposed in a potting part 110. In addition, as described above, the sacrificial member 400 may be formed of a second material having higher reactivity than a first material constituting a terminal 300 and provided as a plurality of sacrificial members 400. In this case, the second material constituting the sacrificial member 400 may not be a conductive metal.

Accordingly, the sacrificial member 400 may be corroded earlier than the terminal 300 due to moisture W entering the first accommodation part 101, thereby delaying corrosion of the terminal 300.

In addition, even when the sacrificial member 400 is damaged due to continuous corrosion, the sacrificial member 400 may be prevented from falling toward a PCB 200 in the housing 100 by the potting part 110. In addition, since one end side of the sacrificial member 400 is exposed to the first accommodation part 101 as described above, the sacrificial member 400 can be easily visually checked when the sacrificial member 400 is damaged due to the continuous corrosion.

Accordingly, in a connector assembly and a vehicle electronic control unit including the same according to one embodiment of the present disclosure, corrosion of the terminal 300 can be delayed to not only prevent the moisture W from entering the housing 100 but also prevent deformation or damage to the potting part 110 due to the corrosion of the terminal 300.

Meanwhile, as illustrated in FIG. 4, a sacrificial member 400 may include an extension 410, which extends from one end side of the sacrificial member 400 disposed in a first accommodation part 101 to the inside of a housing 100, and an auxiliary sacrificial member 420 fixedly provided inside the housing 100 and directly connected to the extension 410. In this case, the auxiliary sacrificial member 420 may be formed to have a greater volume than the sacrificial member 400 and formed of the same material as the sacrificial member 400 and the extension 410 so that the auxiliary sacrificial member 420 may be integrally provided with the housing 100 through insert injection molding.

In addition, although not illustrated in the drawing, the sacrificial member 400 may be provided to be coupled to the housing 100 by a fastening member such as a bolt or nut, or press-fitted to the housing 100. In addition, the sacrificial member 400 may be fixed to the housing 100 through various well-known fastening methods in addition to the above-described fastening methods.

In addition, the housing 100 may further include a third accommodation part 103 formed by a plurality of ribs provided therein to fix the auxiliary sacrificial member 420 connected to the sacrificial member 400 and provided inside the housing 100 as described above. In this case, since the housing 100 may include a plurality of terminals 300, the third accommodation part 103 for fixing the auxiliary sacrificial member 420 as described above may be provided as a plurality of third accommodation parts 103 on various surfaces of the housing.

In addition, the auxiliary sacrificial member 420 may be formed of a third material including a magnesium alloy or the like having higher reactivity than a second material constituting the sacrificial member 400 or a fourth material including an aluminum alloy having higher reactivity than a first material constituting the terminal 300 and lower reactivity than the second material constituting the sacrificial member 400. In this case, the third material or the fourth material may not be a conductive metal like the second material.

Accordingly, in the sacrificial member 400 including the auxiliary sacrificial member 420, when one end side of the sacrificial member 400 disposed in the first accommodation part 101 is corroded earlier than the terminal 300 due to moisture W entering the first accommodation part 101, the auxiliary sacrificial member 420 is corroded along the extension 410, thereby further delaying the corrosion of the terminal 300.

In addition, although not illustrated in the drawing, the housing 100 may further include a guide structure for guiding the sacrificial member 400, which is damaged by continuous corrosion and falls toward a PCB 200, to a side at which the PCB 200 is not disposed and a structure for isolating the falling sacrificial member 400.

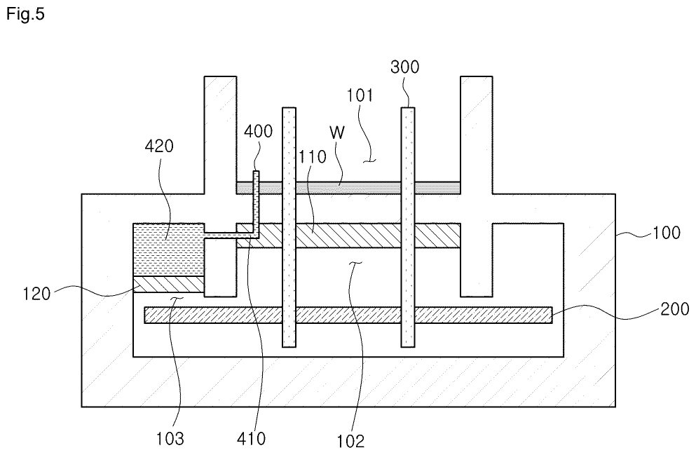

In addition, as illustrated in FIG. 5, in a sacrificial member 400, an extension 410 may be disposed in a potting part 110, and an auxiliary sacrificial member 420 may be accommodated in a third accommodation part 103 and isolated from an inner space of a housing 100 excluding the third accommodation part 103 by an auxiliary potting part 120.

Accordingly, even when the sacrificial member 400 is continuously corroded, and the extension 410 and the auxiliary sacrificial member 420 are damaged, the sacrificial member 400 may be prevented from falling toward a PCB 200 by the potting part 110 and the auxiliary potting part 120. In addition, as described above, since one end side of the sacrificial member 400 is exposed to a first accommodation part 101, the sacrificial member 400 can be easily visually checked when the sacrificial member 400 is continuously corroded and damaged.

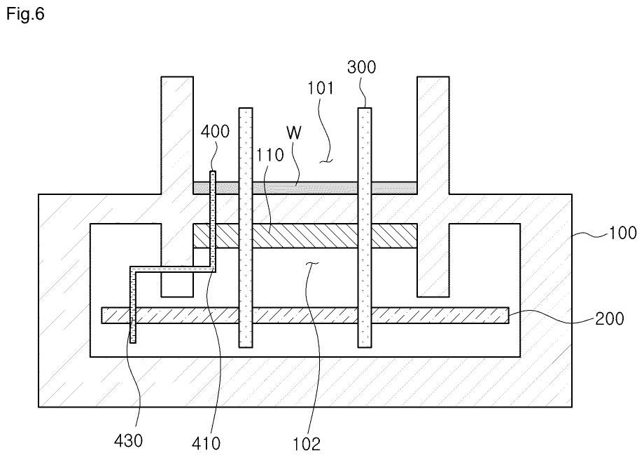

Meanwhile, as illustrated in FIG. 6, a sacrificial member 400 may include an extension 410, which extends from one end side of the sacrificial member 400 disposed in a first accommodation part 101 to the inside of a housing 100, and a PCB connector 430 electrically connected to a PCB 200 at an end portion side of the extension 410.

In this case, in the sacrificial member 400, the extension 410 and the PCB connector 430 may be integrally formed using a conductive metal, and may replace a sensor for detecting moisture entering the PCB 200. In addition, when the PCB 200 electrically connected to the sacrificial member 400 through the PCB connector 430 as described above is electrically disconnected from the PCB connector 430, it may be assumed that moisture W has entered the housing 100, and the PCB 200 may be provided to output a diagnostic trouble code (DTC) or block power to an actuator or the like.

Accordingly, in a connector assembly and a vehicle electronic control unit including the same according to one embodiment of the present disclosure, corrosion of the terminal 300 may be delayed to not only prevent moisture W from entering the housing 100 but also output a DTC or block the power to the actuator or the like in place of a separate moisture detection sensor for detecting moisture entering the housing 100, thereby reducing the manufacturing cost of the product, and furthermore, a fire or the like occurring due to the moisture entering the housing 100 may be prevented.

That is, in the vehicle electronic control unit including the connector assembly according to one embodiment of the present disclosure, even when moisture W enters the terminal 300, the expected lifetime of the terminal 300 can be significantly increased by simply installing the sacrificial member 400.

In addition, as illustrated in FIG. 6, in the sacrificial member 400, a portion of the extension 410 may be firmly and fixedly inserted into a rib or the like provided inside the housing 100, and the extension 410 may be provided through insert injection molding with the housing 100 excluding the PCB connector 430.

Meanwhile, the vehicle electronic control unit including the connector assembly according to one embodiment of the present disclosure may correspond to any electronic unit installed in a vehicle.

As an example, the vehicle electronic control unit including the connector assembly according to one embodiment of the present disclosure may be an engine control unit, a brake control unit, a transmission control unit, an electronic control unit for electric power steering, a body control unit, or a vehicle control unit.

In addition, in the vehicle electronic control unit including the connector assembly according to one embodiment of the present disclosure, the connector assembly formed as described above may be provided as a plurality of connector assemblies, and the connector assembly formed as described above may be formed not only on one surface forming an outer surface of the housing 100 but also on different surfaces.

In addition, although not illustrated in the drawing, the actuator or the like electrically connected to the vehicle electronic control unit including the connector assembly according to one embodiment of the present disclosure may include a connector including a structure for avoiding the sacrificial member 400 to be electrically connected to the terminal 300 for coupling with the connector assembly formed as described above, and not only is not electrically connected to the sacrificial member 400 but also prevents deformation or damage to the sacrificial member 400 due to an external force during fastening or after being completely fastened to the connector assembly.

In a connector assembly and a vehicle electronic control unit including the same according to the present embodiment, since moisture can be prevented from entering a housing from a terminal exposed to the outside of the housing, the durability and reliability of a product can be improved.

In the connector assembly and the vehicle electronic control unit including the same according to the present embodiment, since corrosion of the terminal exposed to the outside of the housing can be significantly delayed, the expected lifetime of the product can be significantly increased.

In the connector assembly and the vehicle electronic control unit including the same according to the present embodiment, since damage to a potting part inside the housing occurring due to corrosion of the terminal located outside the housing spreading to the terminal located inside the housing can be prevented, the durability and reliability or the product can be further improved.

In the connector assembly and the vehicle electronic control unit including the same according to the present embodiment, since moisture entering the housing can be detected without using a separate moisture detecting sensor, manufacturing costs can be significantly reduced.

Although specific embodiments of the connector assembly and the vehicle electronic control unit including the same of the present disclosure have been described, it is clear that various modifications may be made thereto without departing from the scope of the present disclosure.

Therefore, the scope of the present disclosure is defined not by the described embodiments but by the appended claims and equivalents that fall within the scope of the appended claims.

That is, the above-described embodiments should be considered in a descriptive sense only and not for purposes of limitation. The scope of the present disclosure is defined not by the detailed description but by the appended claims, and encompasses all modifications and alterations derived from meanings and the scope and equivalents of the appended claims.

What is claimed is:

1. A connector assembly comprising:
a housing;
a printed circuit board (PCB) provided inside the housing;
a terminal electrically connected to the PCB and formed of a first material such that at least a portion of the terminal is exposed to an outside of the housing; and
a sacrificial member of which at least a portion is adjacent to the terminal and exposed to the outside of the housing,
wherein the sacrificial member is formed of a second material having higher reactivity than the first material.

2. The connector assembly of claim 1, wherein the sacrificial member is electrically connected to the terminal through moisture entering the housing.

3. The connector assembly of claim 1, wherein the housing includes a first accommodation part formed by a rib provided to surround an outer peripheral side of the terminal on an outer side of one surface of the housing in which the terminal is disposed.

4. The connector assembly of claim 3, wherein the at least a portion of the sacrificial member is provided to be disposed in the first accommodation part.

5. The connector assembly of claim 1, wherein the housing includes a potting part provided on an inner side of one surface of the housing in which the terminal is disposed.

6. The connector assembly of claim 5, wherein the housing further including a second accommodation part formed by a rib provided to surround an outer peripheral side of the potting part provided on the inner side of one surface of the housing in which the terminal is disposed.

7. The connector assembly of claim 6, wherein at least a portion of the sacrificial member is provided to be disposed in the second accommodation part.

8. The connector assembly of claim 1, wherein the sacrificial member is riveted to the housing, insert-injection-molded with the housing, coupled to the housing by a fastening member, or press-fitted to the housing.

9. The connector assembly of claim 1, wherein the sacrificial member includes:
an extension extending from one end side of the sacrificial member disposed outside the housing to an inside of the housing; and
an auxiliary sacrificial member fixedly provided inside the housing and directly connected to the extension.

10. The connector assembly of claim 9, wherein the auxiliary sacrificial member is formed of any one of the second material, a third material having higher reactivity than the second material, and a fourth material having higher reactivity than the first material and lower reactivity than the second material.

11. The connector assembly of claim 9, wherein the auxiliary sacrificial member is formed to have a greater volume than the sacrificial member.

12. The connector assembly of claim 9, wherein the extension is disposed in a potting part provided on an inner side of one surface of the housing in which the terminal is disposed.

13. The connector assembly of claim 9, wherein the housing includes a third accommodation part formed by a rib provided to surround an outer peripheral side of the auxiliary sacrificial member on an inner side of one surface of the housing in which the auxiliary sacrificial member is disposed.

14. The connector assembly of claim 13, wherein the housing includes an auxiliary potting part provided in the third accommodation part to surround at least a portion of the auxiliary sacrificial member.

15. The connector assembly of claim 9, wherein the sacrificial member is integrally formed with the auxiliary sacrificial member and provided to be insert-injection-molded with the housing.

16. The connector assembly of claim 1, wherein the sacrificial member includes:
an extension extending from one end side of the sacrificial member disposed outside the housing to an inside of the housing; and
a PCB connector electrically connected to the PCB at an end portion side of the extension.

17. The connector assembly of claim 16, wherein the sacrificial member is integrally formed with the extension and the PCB connector and formed of a conductive metal.

18. The connector assembly of claim 17, wherein the PCB is provided to output a diagnostic trouble code (DTC) or block power when disconnected from the PCB connector.

19. The connector assembly of claim 1, wherein:
the first material includes Cu; and
the second material includes Zn.

20. A vehicle electronic control unit, comprising a connector assembly,
wherein the connector assembly includes:
a housing;
a printed circuit board (PCB) provided inside the housing;
a terminal electrically connected to the PCB and formed of a first material such that at least a portion of the terminal is exposed to an outside of the housing; and
a sacrificial member of which at least a portion is adjacent to the terminal and exposed to the outside of the housing,
wherein the sacrificial member is formed of a second material having higher reactivity than the first material.
